(19) United States
(12) Patent Application Publication
(10) Pub. No.: US 2025/0191979 A1
(43) Pub. Date: Jun. 12, 2025

(54) SUBSTRATE FOR FOREIGN MATERIAL ADHESION INSPECTION, FOREIGN MATERIAL ADHESION INSPECTION DEVICE, AND FOREIGN MATERIAL ADHESION INSPECTION METHOD

(71) Applicant: Mitsubishi Electric Corporation, Tokyo (JP)

(72) Inventor: Kimiharu KUROKI, Tokyo (JP)

(73) Assignee: Mitsubishi Electric Corporation, Tokyo (JP)

(21) Appl. No.: 18/842,740

(22) PCT Filed: May 26, 2022
(86) PCT No.: PCT/JP2022/021590

§ 371 Date: Aug. 29, 2024

(51) Int. Cl. H01L 21/66; H01L 21/67

(52) U.S. Cl. CPC H01L 22/12; H01L 21/67288

(57) ABSTRACT

A substrate for foreign material adhesion inspection according to the disclosure includes a first conductor layer; and an insulating layer provided on the first conductor layer, the insulating layer being thinner than a foreign material to be detected.

### FIELD

The present disclosure relates to a substrate for foreign material adhesion inspection, a foreign material adhesion inspection device, and a foreign material adhesion inspection method.

### BACKGROUND

PTL 1 discloses a chip transfer device including a stage that is movable in an X direction and a Y direction while a wafer divided into a plurality of chips is mounted on the stage, and a collet that picks up each of the chips from the wafer placed on the stage and is movable in a Z direction. The collet is monitored by a monitor through an image. This makes it possible to previously prevent damage, breakage, and the like of the chip that may be caused by damage of the collet itself or a foreign material adhering to the collet.

### CITATION LIST

### Patent Literature

[PTL 1] JP 2008-135455 A

### SUMMARY

### Technical Problem

In a semiconductor device assembling step, generally, a semiconductor wafer is patterned, and the semiconductor wafer is then physically separated into chips in a dicing step or the like. Each of the separated semiconductor chips is picked up by a collet called a die collet and is mounted on a package or the like in a die-bonding step. Thereafter, in a wire-bonding step, the semiconductor chip is connected to a line on the package. As a result, an external terminal of the package is electrically connectable to the semiconductor chip.

In a case where a foreign material adheres to a surface of the die collet adsorbing the semiconductor chip, the foreign material may damage the semiconductor chip. More specifically, impurity contamination caused by adhesion of the foreign material to the semiconductor chip, and dislocation or a defect on a surface layer caused by stress when the foreign material is physically pushed into the semiconductor chip may occur.

In PTL 1, the foreign material adhering to the die collet is monitored using a camera. At this time, detection of the foreign material may become difficult depending on a color of the foreign material.

An object of the present disclosure is to provide a substrate for foreign material adhesion inspection, a foreign material adhesion inspection device, and a foreign material adhesion inspection method that can relax constraint by a color of a foreign material.

### Solution to Problem

A substrate for foreign material adhesion inspection according to the first disclosure includes a first conductor layer; and an insulating layer provided on the first conductor layer, the insulating layer being thinner than a foreign material to be detected.

A substrate for foreign material adhesion inspection according to the second disclosure includes an insulating layer; and a conductor pattern having a linear shape, provided on the insulating layer, the conductor pattern being thinner than a foreign material to be detected.

A substrate for foreign material adhesion inspection according to the third disclosure includes an insulating layer; and a plurality of conductor layers provided adjacently to each other on an upper surface of the insulating layer, wherein an interval between the plurality of conductor layers is smaller than a foreign material to be detected.

A foreign material adhesion inspection method according to the fourth disclosure includes bringing a pickup surface of a die collet into contact with, of a substrate for foreign material adhesion inspection including a first conductor layer, an insulating layer provided on the first conductor layer, and a second conductor layer provided on the insulating layer, an upper surface of the second conductor layer, and then measuring a physical quantity between the first conductor layer and the second conductor layer; and determining presence/absence of adhesion of a foreign material to the pickup surface from the physical quantity.

A foreign material adhesion inspection method according to the fifth disclosure includes measuring, in a state where a pickup surface made of a conductor held by a die collet is in contact with an upper surface of an insulating layer of a substrate for foreign material adhesion inspection including a conductor layer and the insulating layer provided on the conductor layer, a physical quantity between the conductor layer and the pickup surface; and determining presence/absence of adhesion of a foreign material to the pickup surface from the physical quantity.

A foreign material adhesion inspection method according to the sixth disclosure includes bringing a pickup surface of a die collet into contact with, of a substrate for foreign material adhesion inspection including an insulating layer and a conductor pattern having a linear shape, provided on the insulating layer, an upper surface of the conductor pattern, and then measuring a physical quantity between one side and another side of a portion of the conductor pattern with which the die collet is in contact; and determining presence/absence of adhesion of a foreign material to the pickup surface from the physical quantity.

A foreign material adhesion inspection method according to the seventh disclosure includes bringing a pickup surface of a die collet into contact with, of a substrate for foreign material adhesion inspection including an insulating layer and a plurality of conductor patterns provided on the insulating layer, upper surfaces of the plurality of conductor patterns, and then measuring a physical quantity between the plurality of conductor patterns; and determining presence/absence of adhesion of a foreign material to the pickup surface from the physical quantity.

A foreign material adhesion inspection method according to the eighth disclosure includes bringing a pickup surface of a die collet into contact with, of a substrate for foreign material adhesion inspection including an insulating layer, and a conductor pattern bent and provided on an upper surface of the insulating layer and including a first portion and a second portion adjacent to each other, the first portion and the second portion, and then measuring a physical quantity between one side and another side of a portion of the conductor pattern with which the die collet is in contact; and determining presence/absence of adhesion of a foreign material to the pickup surface from the physical quantity.

### Advantageous Effects of Invention

In the substrate for foreign material adhesion inspection and the foreign material adhesion inspection method according to the first to eighth disclosures, presence/absence of adhesion of a foreign material to the die collet can be determined from variation in physical quantity caused by contact of the substrate for foreign material adhesion inspection and the die collet. This makes it possible to relax the constraint by the color of the foreign material.

### BRIEF DESCRIPTION OF DRAWINGS

FIG. 1 is a side view of a foreign material adhesion inspection device according to Embodiment 1.

FIG. 2 is a diagram to explain the die collet according to Embodiment 1.

FIG. 3 is a diagram to explain a pickup surface according to Embodiment 1.

FIG. 4 is a side view of a foreign material adhesion inspection device according to Embodiment 2.

FIG. 5 is a plan view of the foreign material adhesion inspection device according to Embodiment 2.

FIG. 6 is a diagram to explain the pickup surface according to Embodiment 2.

FIG. 7 is a side view of a foreign material adhesion inspection device according to Embodiment 3.

FIG. 8 is a plan view of the foreign material adhesion inspection device according to Embodiment 3.

FIG. 9 is a side view of a foreign material adhesion inspection device according to Embodiment 4.

FIG. 10 is a plan view of the foreign material adhesion inspection device according to Embodiment 4.

FIG. 11 is a side view of a foreign material adhesion inspection device according to Embodiment 5.

FIG. 12 is a plan view of the foreign material adhesion inspection device according to Embodiment 5.

FIG. 13 is a plan view of the foreign material adhesion inspection device according to a modification of Embodiment 5.

### DESCRIPTION OF EMBODIMENTS

A substrate for foreign material adhesion inspection, a foreign material adhesion inspection device, and a foreign material adhesion inspection method according to each embodiment are described with reference to drawings. Identical or corresponding constitutional elements are given the same reference numerals, and the repeated description of such constitutional elements may be omitted.

### Embodiment 1

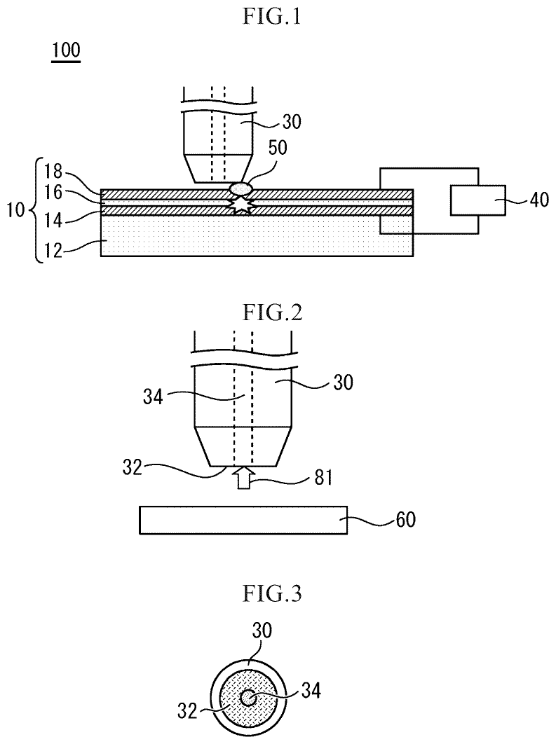

FIG. 1 is a side view of a foreign material adhesion inspection device 100 according to Embodiment 1. The foreign material adhesion inspection device 100 includes a substrate for foreign material adhesion inspection 10 and a measurement instrument 40. The substrate for foreign material adhesion inspection 10 includes an insulating substrate 12, a conductor layer 14 provided on the insulating substrate 12, an insulating layer 16 provided on the conductor layer 14, and a conductor layer 18 provided on the insulating layer 16. The insulating layer 16 is thinner than a foreign material 50 to be detected. The measurement instrument 40 is connected to the conductor layer 14 and the conductor layer 18. The measurement instrument 40 measures a physical quantity between the conductor layer 14 and the conductor layer 18.

The insulating substrate 12 is, for example, a glass epoxy substrate or a ceramic substrate. The conductor layer 14 is a conductive resistor, and is a thin plate or a thin film. The conductor layer 14 is desirably made of a metal such as copper, gold, and aluminum. The material of the conductor layer 14 is not limited thereto as long as a resistance value of the conductor layer 14 is known.

The conductor layer 18 is a conductive resistor. The conductor layer 18 is desirably a thin film made of a soft metal such as copper, gold, and aluminum so as to be deformed or broken by pushing of the foreign material 50 and a die collet 30. The material of the conductor layer 18 is not limited thereto as long as a resistance value of the conductor layer 18 is known. A thickness of the conductor layer 18 is not limited, and is, for example, several tens μm to several hundred μm.

The insulating layer 16 is an extremely thin film easily deformed by the foreign material 50. When the insulating layer 16 is deformed, the conductor layer 14 and the conductor layer 18 are conducted. A material of the insulating layer 16 is not limited, but is preferably a rubber-based film such as a nitrile film, a silicone film, and an urethan film, a vinyl-based film, or an organic film such as a polyester film.

FIG. 2 is a diagram to explain the die collet 30 according to Embodiment 1. FIG. 3 is a diagram to explain a pickup surface 32 according to Embodiment 1. The die collet 30 has a function of adsorbing a semiconductor chip 60 picked up by a push-up pin or the like and conveying the semiconductor chip 60 to a package such as a lead frame in a die-bonding step. The die collet 30 may have a function of pressing and scrubbing the semiconductor chip 60 in the die-bonding step.

The die collet 30 is made of ceramics such as zirconia, or ruby. A surface of the die collet 30 coming into contact with the semiconductor chip 60 is referred to as the pickup surface 32. The pickup surface 32 includes a suction port 34. The suction port 34 penetrates through the die collet 30. In the die-bonding step, vacuuming is performed from the suction port 34 in a direction indicated by an arrow 81, and the semiconductor chip 60 is adsorbed and held to the pickup surface 32. This makes it possible to transfer the semiconductor chip 60. A shape of a front end portion of the die collet 30 is not limited to a truncated pyramid or a truncated cone. A shape of the pickup surface 32 is not limited to a flat shape.

Next, a foreign material adhesion inspection method according to the present embodiment is described. Before the die collet 30 and the substrate for foreign material adhesion inspection 10 are brought into contact with each other, the measurement instrument 40 first measures a resistance value between the conductor layer 14 and the conductor layer 18.

Subsequently, the pickup surface 32 of the die collet 30 is brought into contact with an upper surface of the conductor layer 18 of the substrate for foreign material adhesion inspection 10. At this time, the pickup surface 32 is pressed in parallel with the upper surface of the conductor layer 18. FIG. 1 illustrates a state where the die collet 30 in which the foreign material 50 adheres to the pickup surface 32 is pressed against the substrate for foreign material adhesion inspection 10. At this time, vacuuming of the die collet 30 is not performed. A relative position between the die collet 30 and the substrate for foreign material adhesion inspection 10 is fixed such that, for example, when the upper surface of the conductor layer 18 is set as a reference surface, a height of the pickup surface 32 is coincident with the reference surface. A height of the die collet 30 and a parallelism with the substrate surface are detected by a current sensor, a pressure sensor, an appearance inspection by a camera, and the like.

After the substrate for foreign material adhesion inspection 10 and the die collet 30 are brought into contact with each other, the measurement instrument 40 measures the resistance value between the conductor layer 14 and the conductor layer 18. In a case where the foreign material 50 adheres to the die collet 30, a load is locally applied to a portion of the substrate for foreign material adhesion inspection 10 just below the foreign material 50. Therefore, the conductor layer 18 is deformed by the foreign material 50, and the insulating layer 16 is broken. As a result, the conductor layer 14 and the conductor layer 18 are short-circuited. Therefore, the resistance value between the conductor layer 14 and the conductor layer 18 is varied before and after contact of the die collet 30.

The height of the die collet 30 is controlled as described above. Therefore, in a case where no foreign material 50 adheres to the pickup surface 32, the insulating layer 16 is not broken. As a result, the substrate for foreign material adhesion inspection 10 is not physically changed by contact of the die collet 30, and the resistance value between the conductor layer 14 and the conductor layer 18 is not varied.

Subsequently, the resistance values before and after contact of the die collet 30 are compared. Presence/absence of adhesion of a foreign material to the pickup surface 32 is determined from the resistance value between the conductor layer 14 and the conductor layer 18. In a case where the foreign material 50 is absent, the resistance value between the conductor layer 14 and the conductor layer 18 indicates an open-circuit state, whereas in a case where the foreign material 50 is present, the resistance value between the conductor layer 14 and the conductor layer 18 indicates a short-circuit state. The measurement instrument 40 determines whether the conductor layer 14 and the conductor layer 18 have been short-circuited.

The foreign material 50 is a fine fragment, for example, a metal such as gold, copper, and platinum, or an organic substance such as a foreign material derived from a human body. A size of the foreign material 50 is not limited, and is, for example, about several micrometers to about several millimeters. When the semiconductor chip 60 is picked up in the state where the foreign material 50 adheres to the pickup surface 32, the picked-up semiconductor chip 60 may be damaged or contaminated by the foreign material 50. Such a semiconductor chip 60 is determined to be defective in characteristics or appearance, and cannot be used as a product.

In contrast, in the present embodiment, presence/absence of adhesion of the foreign material 50 to the die collet 30 can be determined from variation in resistance value caused by contact of the substrate for foreign material adhesion inspection 10 and the die collet 30. In addition, as compared with a case where the foreign material 50 is detected by a camera, the foreign material 50 can be detected irrespective of a color of the foreign material 50, and constraint by the color of the foreign material 50 can be relaxed. Further, in the present embodiment, the foreign material 50 can be detected even when the foreign material 50 has conductivity or does not have conductivity. Further, it is sufficient to set the thickness of the insulating layer 16 based on the anticipated foreign material 50, which makes it possible to relax constraint by the size of the foreign material 50.

In the present embodiment, presence/absence of the foreign material 50 is determined from the resistance value. The physical quantity measured by the measurement instrument 40 is not limited to the resistance value as long as it is possible to determine that the conductor layer 14 and the conductor layer 18 have been short-circuited. The measurement of the physical quantity between the conductor layer 14 and the conductor layer 18 after the substrate for foreign material adhesion inspection 10 and the die collet 30 are brought into contact with each other may be performed in a state where the substrate for foreign material adhesion inspection 10 and the die collet 30 are separated from each other or in contact with each other. Further, whether the conductor layer 14 and the conductor layer 18 have been short-circuited may be determined by the measurement instrument 40, or by a person based on the measurement value.

These modifications can be applied, as appropriate, to substrates for foreign material adhesion inspection, foreign material adhesion inspection devices, and foreign material adhesion inspection methods according to the following embodiments. Note that the substrates for foreign material adhesion inspection, the foreign material adhesion inspection devices, and the foreign material adhesion inspection methods according to the following embodiments are similar to those of the first embodiment in many respects, and thus differences between the substrates for foreign material adhesion inspection, the foreign material adhesion inspection devices, and the foreign material adhesion inspection methods according to the following embodiments and those of the first embodiment will be mainly described below.

### Embodiment 2

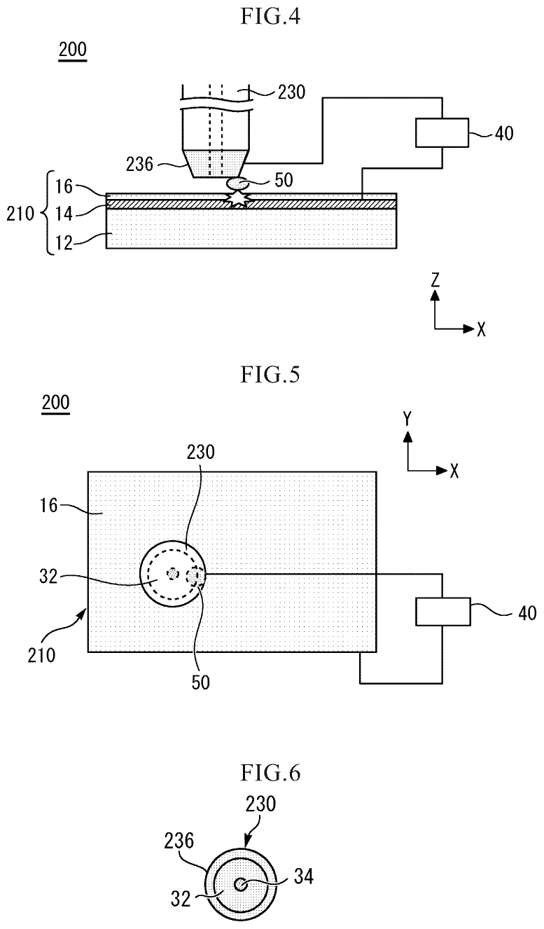

FIG. 4 is a side view of a foreign material adhesion inspection device 200 according to Embodiment 2. FIG. 5 is a plan view of the foreign material adhesion inspection device 200 according to Embodiment 2. FIG. 6 is a diagram to explain the pickup surface 32 according to Embodiment 2. The foreign material adhesion inspection device 200 includes a substrate for foreign material adhesion inspection 210 and the measurement instrument 40. A configuration of the substrate for foreign material adhesion inspection 210 is similar to the configuration of the substrate for foreign material adhesion inspection 10 except that the conductor layer 18 is not provided. The substrate for foreign material adhesion inspection 210 includes the insulating substrate 12, the conductor layer 14 provided on the insulating substrate 12, and the insulating layer 16 provided on the conductor layer 14. The insulating layer 16 is thinner than the foreign material 50 to be detected.

A die collet 230 includes a conductor portion 236. The conductor portion 236 at least includes the pickup surface 32, and is provided at a front end of the die collet 230. The other configuration of the die collet 230 is similar to the configuration of the die collet 30.

The measurement instrument 40 measures a physical quantity between the conductor layer 14 and the conductor portion 236 of the die collet 230. The measurement instrument 40 includes a function of measuring a capacitance in addition to the resistance value.

Next, a foreign material adhesion inspection method according to the present embodiment is described. Before the die collet 230 and the substrate for foreign material adhesion inspection 210 are brought into contact with each other, the measurement instrument 40 first measures a resistance value and a capacitance as the physical quantities between the conductor layer 14 and the conductor layer 18.

Subsequently, a resistance value and a capacitance between the conductor 14 and the pickup surface 32 are measured while the pickup surface 32 made of a conductor held by the die collet 230 is in contact with an upper surface of the insulating layer 16. From the resistance value and the capacitance, presence/absence of adhesion of a foreign material to the pickup surface 32 is determined.

In a case of using the die collet 230 to which the foreign material 50 adheres, the insulating layer 16 is broken by the foreign material 50. As a result, the conductor layer 14 and the conductor portion 236 are connected through the foreign material 50. In a case where the foreign material 50 has conductivity, the conductor layer 14 and the conductor portion 236 are short-circuited. In contrast, in a case where the foreign material 50 is absent, the conductor layer 14 and the conductor portion 236 are open-circuited. The measurement instrument 40 measures the resistance value between the conductor layer 14 and the conductor portion 236, and compares the resistance values before and after contact of the die collet 230. Based on the comparison, the measurement instrument 40 determines whether the conductor layer 14 and the conductor portion 236 have been short-circuited. This makes it possible to determine presence/absence of adhesion of the foreign material 50 to the pickup surface 32.

In a case where the foreign material 50 is an insulator, the conductor layer 14, the insulating layer 16 and the foreign material 50, and the conductor portion 236 form a capacitor. An interval between the conductor layer 14 and the conductor portion 236 is varied by presence/absence of the foreign material 50. Therefore, a capacitance value of the capacitor is varied. The measurement instrument 40 measures the capacitance value between the conductor layer 14 and the conductor portion 236, and compares the capacitance values before and after contact of the die collet 230. This makes it possible to determine presence/absence of adhesion of the foreign material 50 to the pickup surface 32.

In the present embodiment, the conductor layer 18 is not provided, but the conductor portion 236 is provided on the die collet 230. Therefore, in the substrate for foreign material adhesion inspection 10, electric connection of the conductor layer 14 is only required, which makes it possible to realize a unipolar state. Alternatively, the conductor layer 14 may be electrically connected to a GND wiring provided on a housing or the like. As described above, it is possible to simplify the structure and the electric connection of the substrate for foreign material adhesion inspection 10.

The physical quantities measured by the measurement instrument 40 are not limited to the resistance value and the capacitance as long as it is possible to determine whether the conductor layer 14 and the conductor portion 236 have been short-circuited, or to determine presence/absence of the insulating foreign material 50 between the conductor layer 14 and the conductor portion 236. For example, the measurement instrument 40 may detect variation of a charge amount.

### Embodiment 3

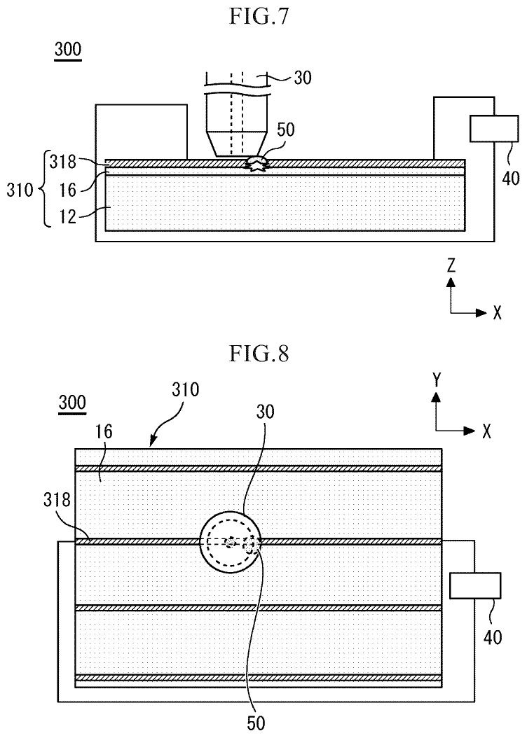

FIG. 7 is a side view of a foreign material adhesion inspection device 300 according to Embodiment 3. FIG. 8 is a plan view of the foreign material adhesion inspection device 300 according to Embodiment 3. The foreign material adhesion inspection device 300 includes a substrate for foreign material adhesion inspection 310 and the measurement instrument 40. The substrate for foreign material adhesion inspection 310 includes the insulating substrate 12, the insulating layer 16 provided on the insulating substrate 12, and a plurality of linear conductor patterns 318 provided on the insulating layer 16. A material of the insulating substrate 12 is similar to the material of the insulating substrate 12 according to Embodiment 1. The die collet 30 is similar to the die collet 30 according to Embodiment 1.

Each of the conductor patterns 318 is thinner than the foreign material 50 to be detected, and is finer than the foreign material 50. An interval between adjacent two of the plurality of conductor patterns 318 is, for example, greater than a radius of the pickup surface 32 of the die collet 30.

The measurement instrument 40 measures a physical quantity between one side and the other side of a portion of the conductor pattern 318 with which the die collet 30 comes into contact. The measurement instrument 40 is connected to, for example, both ends of one of the conductor patterns 318.

Next, a foreign material adhesion inspection method according to the present embodiment is described. Before the die collet 30 and the substrate for foreign material adhesion inspection 310 are brought into contact with each other, the measurement instrument 40 first measures a resistance value of one of the conductor patterns 318. Subsequently, the pickup surface 32 of the die collet 30 is brought into contact with an upper surface of the one of the conductor patterns 318 on the substrate for foreign material adhesion inspection 310. Thereafter, the measurement instrument 40 measures the resistance value between one side and the other side of a portion of the one of the conductor patterns 318 with which the die collet 30 comes into contact, and presence/absence of adhesion of a foreign material to the pickup surface 32 is determined from the resistance value.

In a case where the foreign material 50 adheres to the die collet 30, a load is locally applied to a portion of the one of the conductor patterns 318 just below the foreign material 50, and the one of the conductor patterns 318 is physically broken. As a result, the resistance value of the one of the conductor patterns 318 is varied before and after contact of the die collet 30. In a case where the foreign material 50 is absent, the resistance value of the one of the conductor patterns 318 indicates a short-circuit state, whereas in a case where the foreign material 50 is present, the resistance value of the one of the conductor patterns 318 indicates an open-circuit state. The measurement instrument 40 determines whether the one of the conductor patterns 318 has been broken.

In the present embodiment, it is sufficient to provide one layer of the conductor patterns 318, and electric connection to the die collet 30 is unnecessary, which makes it possible to simplify the foreign material adhesion inspection device 300. Further, when the plurality of conductor patterns 318 are formed with intervals each greater than the radius of the pickup surface 32, it is possible to perform inspection a plurality of times by changing connection of the measurement instrument 40. This makes it possible to reduce a running cost.

Further, arranging the soft insulating layer 16 below the conductor patterns 318 can cause the conductor patterns 318 to be easily broken, which makes it possible to improve detection sensitivity. Thus, the thickness of the insulating layer 16 according to the present embodiment may be made greater than the thickness of the insulating layer 16 according to Embodiment 1. In a case where the insulating substrate 12 has flexibility or elasticity, the insulating layer 16 may be omitted.

The number of conductor patterns 318 is not limited, and it is sufficient to provide one or more conductor patterns 318. In the present embodiment, presence/absence of the foreign material 50 is determined from the resistance value. The physical quantity measured by the measurement instrument 40 is not limited to the resistance value as long as it is possible to determine break of each of the conductor patterns 318. The measurement of the physical quantity of the conductor pattern 318 after the substrate for foreign material adhesion inspection 310 and the die collet 30 are brought into contact with each other may be performed in a state where the substrate for foreign material adhesion inspection 310 and the die collet 30 are separated from each other or in contact with each other.

As a modification of the present embodiment, it is sufficient for each of the conductor patterns 318 to be thinner than a foreign material to be detected, and each of the conductor patterns 318 may not be finer than the foreign material 50. Even in this case, the resistance value of the conductor pattern 318 is slightly varied due to formation of chipping such as a hole in the conductor pattern 318 by the foreign material 50. Therefore, it is possible to determine presence/absence of adhesion of the foreign material 50 to the pickup surface 32.

### Embodiment 4

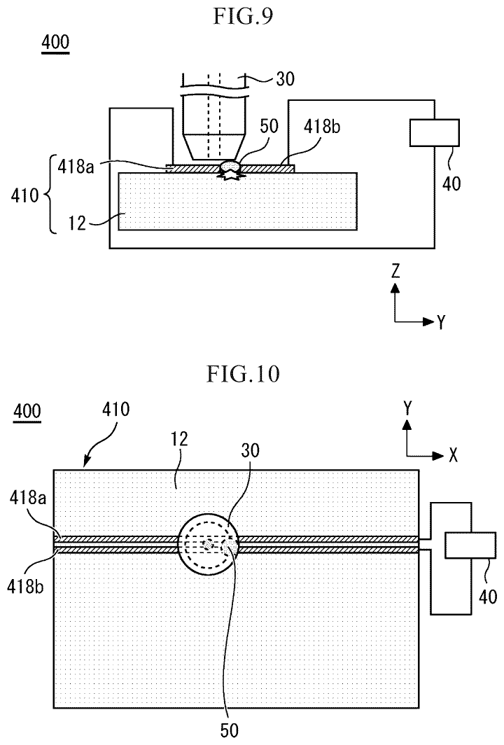

FIG. 9 is a side view of a foreign material adhesion inspection device 400 according to Embodiment 4. FIG. 10 is a plan view of the foreign material adhesion inspection device 400 according to Embodiment 4. The foreign material adhesion inspection device 400 includes a substrate for foreign material adhesion inspection 410 and the measurement instrument 40. The substrate for foreign material adhesion inspection 410 includes the insulating substrate 12 and a plurality of conductor layers provided adjacently to each other on an upper surface of the insulating substrate 12. The plurality of conductor layers are a plurality of conductor patterns 418a and 418b separately provided on the insulating substrate 12. The measurement instrument 40 measures a physical quantity between the plurality of conductor patterns 418a and 418b. The material of the insulating substrate 12 is similar to the material of the insulating substrate 12 according to Embodiment 1. The die collet 30 is similar to the die collet 30 according to Embodiment 1.

The plurality of conductor patterns 418a and 418b each have, for example, a ribbon shape. An interval between the plurality of conductor patterns 418a and 418b is smaller than the foreign material 50 to be detected. The conductor patterns 418a and 418b are thin plates or thin films having conductivity. The conductor patterns 418a and 418b are desirably made of a metal such as copper, gold, and aluminum. The materials of the conductor patterns 418a and 418b are not limited as long as resistance values thereof are known.

Next, a foreign material adhesion inspection method according to the present embodiment is described. Before the die collet 30 and the substrate for foreign material adhesion inspection 410 are brought into contact with each other, the measurement instrument 40 first measures a resistance value and a capacitance as the physical quantities between the plurality of conductor patterns 418a and 418b.

Subsequently, after the pickup surface 32 of the die collet 30 is brought into contact with upper surfaces of the plurality of conductor patterns 418a and 418b on the substrate for foreign material adhesion inspection 410, the measurement instrument 40 measures the resistance value and the capacitance between the plurality of conductor patterns 418a and 418b. From the resistance value and the capacitance, presence/absence of adhesion of a foreign material to the pickup surface 32 is determined.

In a case of using the die collet 30 to which the foreign material 50 adheres, the plurality of conductor patterns 418a and 418b are connected by the foreign material 50. In a case where the foreign material 50 has conductivity, the conductor patterns 418a and 418b are short-circuited. In contrast, in a case where the foreign material 50 is absent, the conductor patterns 418a and 418b are open-circuited. The measurement instrument 40 measures the resistance value between the conductor patterns 418a and 418b, and compares the resistance values before and after contact of the die collet 30. Based on the comparison, the measurement instrument 40 determines whether the conductor patterns 418a and 418b have been short-circuited. This makes it possible to determine presence/absence of adhesion of the foreign material 50 to the pickup surface 32.

In a case where the foreign material 50 is an insulator, the conductor pattern 418a, the foreign material 50, and the conductor pattern 418b form a capacitor. A capacitance value of the capacitor is varied by presence/absence of the foreign material 50. The measurement instrument 40 measures the capacitance value between the conductor patterns 418a and 418b, and compares the capacitance values before and after contact of the die collet 230. This makes it possible to determine presence/absence of adhesion of the foreign material 50 to the pickup surface 32.

In the present embodiment, in the case where the foreign material 50 has conductivity, the measurement instrument 40 detects that a state between the conductor patterns 418a and 418b is changed from the open-circuit state to the short-circuit state. In contrast, in Embodiment 3, the measurement instrument 40 detects that the state is changed from the short-circuit state to the open-circuit state. In the present embodiment, as compared with Embodiment 3, it is possible to suppress erroneous detection caused by the open state between the electrodes or voltage drop due to circuit contact failure. Therefore, the detection sensitivity of the measurement instrument 40 can be reduced, and the foreign material 50 can be detected at high speed. This makes it possible to shorten an inspection time.

Even in the present embodiment, it is sufficient to provide one layer of the conductor patterns 418a and 418b, and electric connection to the die collet 30 is unnecessary, which makes it possible to simplify the foreign material adhesion inspection device 400. In addition, when the conductor patterns 418a and 418b are arranged in parallel with each other, the conductor patterns 418a and 418b and the electrodes of the measurement instrument 40 can be connected on one side of the substrate for foreign material adhesion inspection 410. This makes it possible to shorten the wiring of the measurement instrument 40 and to downsize the foreign material adhesion inspection device 400.

The number of conductor patterns 418a and 418b is not limited, and may be three or more. The smaller foreign material 50 can be detected as line widths and a line interval of the conductor patterns 418a and 418b are narrower. Further, the conductor patterns 418a and 418b are not limited to the linear shapes as long as the conductor patterns 418a and 418b are provided adjacently to each other with an interval smaller than the foreign material 50.

The physical quantities measured by the measurement instrument 40 are not limited to the resistance value and the capacitance as long as it is possible to determine whether the conductor patterns 418a and 418b have been short-circuited, or to determine presence/absence of the insulating foreign material 50 between the conductor patterns 418a and 418b. The measurement of the physical quantities between the conductor patterns 418a and 418b after the substrate for foreign material adhesion inspection 410 and the die collet 30 are brought into contact with each other may be performed in a state where the substrate for foreign material adhesion inspection 410 and the die collet 30 are separated from each other or in contact with each other.

### Embodiment 5

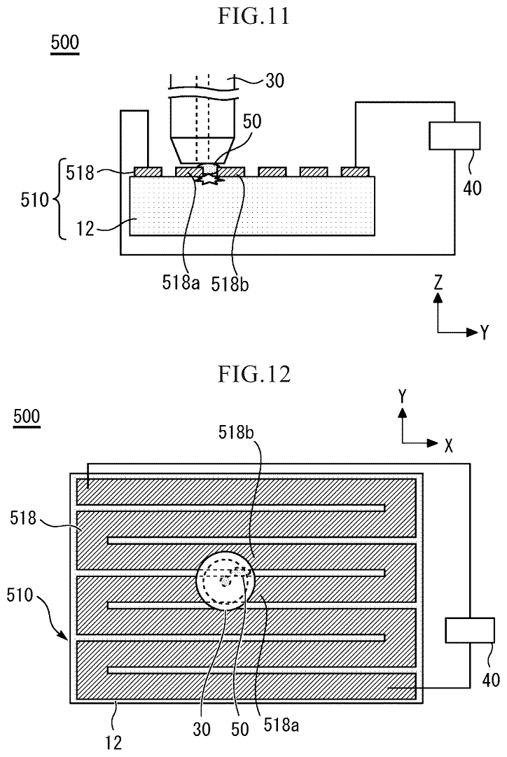

FIG. 11 is a side view of a foreign material adhesion inspection device 500 according to Embodiment 5. FIG. 12 is a plan view of the foreign material adhesion inspection device 500 according to Embodiment 5. The foreign material adhesion inspection device 500 includes a substrate for foreign material adhesion inspection 510 and the measurement instrument 40. The substrate for foreign material adhesion inspection 510 includes the insulating substrate 12 and a conductor pattern 518 bent and provided on the upper surface of the insulating substrate 12. The material of the insulating substrate 12 is similar to the material of the insulating substrate 12 according to Embodiment 1. The die collet 30 is similar to the die collet 30 according to Embodiment 1.

The conductor pattern 518 has, for example, a meandering shape. The conductor pattern 518 includes a first portion 518a and a second portion 518b adjacent to each other. An interval between the first portion 518a and the second portion 518b is smaller than the foreign material 50 to be detected. The interval between the first portion 518a and the second portion 518b may be fixed. The first portion 518a and the second portion 518b correspond to the plurality of conductor layers provided adjacently to each other on the upper surface of the insulating substrate 12.

The measurement instrument 40 measures a physical quantity between one side and the other side of a portion of the conductor pattern 518 with which the die collet 30 is in contact. The measurement instrument 40 is connected to, for example, both ends of the conductor pattern 518 to measure a resistance value between the both ends of the conductor pattern 518.

Next, a foreign material adhesion inspection method according to the present embodiment is described. Before the die collet 30 and the substrate for foreign material adhesion inspection 510 are brought into contact with each other, the measurement instrument 40 first measures a resistance value of the conductor pattern 518. Subsequently, the pickup surface 32 of the die collet 30 is brought into contact with the first portion 518a and the second portion 518b of the substrate for foreign material adhesion inspection 510. Thereafter, the measurement instrument 40 measures a resistance value between one side and the other side of a portion of the conductor pattern 518 with which the die collet 30 is in contact, and presence/absence of adhesion of the foreign material 50 to the pickup surface 32 is determined from the resistance value.

In a case where the foreign material 50 adheres to the die collet 30, the first portion 518a and the second portion 518b are connected by the foreign material 50. Therefore, in a case where the foreign material 50 has conductivity, the resistance value of the conductor pattern 518 is varied before and after contact of the die collet 30. This makes it possible to determine presence/absence of adhesion of the foreign material 50 to the pickup surface 32. The resistance value of the conductor pattern 518 is preferably several hundred kΩ to several tens MΩ in a state of no foreign material 50. This makes it possible to use the measurement instrument 40 generally easily available.

Even in the present embodiment, it is sufficient to provide one layer of the conductor pattern 518, and electric connection to the die collet 30 is unnecessary, which makes it possible to simplify the foreign material adhesion inspection device 500. In the present embodiment, a number of portions adjacent to each other can be formed in the conductor pattern 518. Therefore, the foreign material 50 can be detected within a range wider than a range according to Embodiment 4. Even when the conductor pattern 518 is partially short-circuited by the foreign material 50, the foreign material 50 can be detected by the other portions. Therefore, it is possible to use the foreign material adhesion inspection device 500 for a long time or a plurality of times, and to reduce a material cost of the conductor pattern 518.

The conductor pattern 518 is not limited to the meandering shape as long as the conductor pattern 518 includes the first portion 518a and the second portion 518b adjacent to each other. The smaller foreign material 50 can be detected as a line width and an interval of the conductor pattern 518 are narrower. The physical quantity measured by the measurement instrument 40 is not limited to the resistance value as long as connection of the first portion 518a and the second portion 518b caused by the foreign material 50 can be determined. The measurement of the physical quantity of the conductor pattern 518 after the substrate for foreign material adhesion inspection 510 and the die collet 30 are brought into contact with each other may be performed in a state where the substrate for foreign material adhesion inspection 510 and the die collet 30 are separated from each other or in contact with each other.

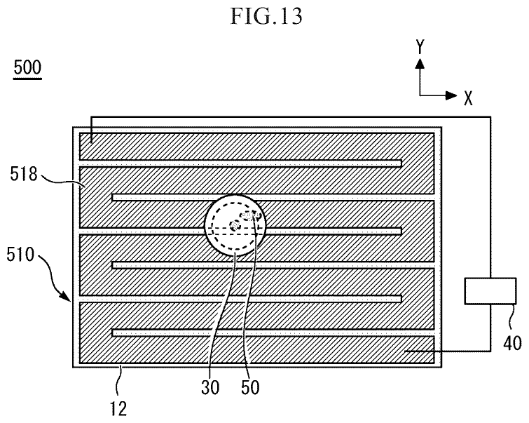

FIG. 13 is a plan view of the foreign material adhesion inspection device 500 according to a modification of Embodiment 5. The foreign material adhesion inspection device 500 can detect the foreign material 50 not only in the case where the foreign material 50 connects the first portion 518a and the second portion 518b as illustrated in FIG. 12 but also in a case where the foreign material 50 is present on the conductor pattern 518 as illustrated in FIG. 13. In this case, as in Embodiment 3, the conductor pattern 518 is preferably thinner than the foreign material 50. The conductor pattern 518 may be finer than the foreign material 50. The resistance value of the conductor pattern 518 is varied due to formation of chipping such as a hole and a break of the conductor pattern 518 by the foreign material 50. Therefore, it is possible to determine presence/absence of adhesion of the foreign material 50 to the pickup surface 32.

According to the modification, the foreign material 50 can be detected at an optional position on the conductor pattern 518. In this case, it is sufficient to strictly manage positional accuracy of the die collet 30 only in the Z direction, and to limit positions of the die collet 30 in the X and Y directions without departing from the conductor pattern 518. This makes it possible to shorten a detection time and to reduce an operational cost.

The substrate for foreign material adhesion inspection 510 may include the insulating layer 16 between the insulating substrate 12 and the conductor pattern 518 as in Embodiment 3. Arranging the soft insulating layer 16 below the conductor pattern 518 can cause the conductor pattern 518 to be easily broken, which makes it possible to improve detection sensitivity by the chipping of the conductor pattern 518.

Note that the technical features described in the above embodiments may be combined as appropriate. Furthermore, the present disclosure is not limited to the above-described embodiments, and can be modified within the scope of the present disclosure.

### REFERENCE SIGNS LIST

10 substrate for foreign material adhesion inspection, 12 insulating substrate, 14 conductor layer, 16 insulating layer, 18 conductor layer, 30 die collet, 32 pickup surface, 34 suction port, 40 measurement instrument, 50 foreign material, 60 semiconductor chip, 100 foreign material adhesion inspection device, 200 foreign material adhesion inspection device, 210 substrate for foreign material adhesion inspection, 230 die collet, 236 conductor portion, 300 foreign material adhesion inspection device, 310 substrate for foreign material adhesion inspection, 318 conductor pattern, 400 foreign material adhesion inspection device, 410 substrate for foreign material adhesion inspection, 418a conductor pattern, 418b conductor pattern, 500 foreign material adhesion inspection device, 510 substrate for foreign material adhesion inspection, 518 conductor pattern, 518a first portion, 518b second portion

1. A substrate for foreign material adhesion inspection, comprising:
a first conductor layer;
an insulating layer provided on the first conductor layer, the insulating layer being thinner than a foreign material to be detected; and
a second conductor layer provided on the insulating layer.

2.-6. (canceled)

7. A foreign material adhesion inspection device, comprising:
the substrate for foreign material adhesion inspection according to claim 1; and
a measurement instrument configured to measure a physical quantity between the first conductor layer and the second conductor layer.

8. The foreign material adhesion inspection device according to claim 7, wherein the insulating layer is a rubber-based, vinyl-based, or organic thin film.

9. The foreign material adhesion inspection device according to claim 7, wherein the measurement instrument measures a resistance value between the first conductor layer and the second conductor layer, to determine whether the first conductor layer and the second conductor layer are short-circuited.

10. A foreign material adhesion inspection device, comprising:
a substrate for foreign material adhesion inspection including a first conductor layer and an insulating layer provided on the first conductor layer; and
a measurement instrument configured to measure a physical quantity between the first conductor layer and a conductor portion of a die collet, wherein the insulating layer is thinner than a foreign material to be detected, and
the measurement instrument measures a resistance value between the first conductor layer and the conductor portion, to determine whether the first conductor layer and the conductor portion are short-circuited.

11. The foreign material adhesion inspection device according to claim 10, wherein the insulating layer is a rubber-based, vinyl-based, or organic thin film.

12. (canceled)

13. The foreign material adhesion inspection device according to claim 10, wherein the measurement instrument measures a capacitance value between the first conductor layer and the conductor portion.

14.-23. (canceled)

24. A foreign material adhesion inspection method, comprising:
bringing a pickup surface of a die collet into contact with, of a substrate for foreign material adhesion inspection including a first conductor layer, an insulating layer provided on the first conductor layer, and a second conductor layer provided on the insulating layer, an upper surface of the second conductor layer, and then measuring a physical quantity between the first conductor layer and the second conductor layer; and
determining presence/absence of adhesion of a foreign material to the pickup surface from a change in the physical quantity before and after the contact of the pickup surface.

25. The foreign material adhesion inspection method according to claim 24, wherein the insulating layer is broken by the foreign material, and the first conductor layer and the second conductor layer are short-circuited.

26. A foreign material adhesion inspection method, comprising:
measuring, in a state where a pickup surface made of a conductor held by a die collet is in contact with an upper surface of an insulating layer of a substrate for foreign material adhesion inspection including a conductor layer and the insulating layer provided on the conductor layer, a physical quantity between the conductor layer and the pickup surface; and
determining presence/absence of adhesion of a foreign material to the pickup surface from a change in the physical quantity between before the pickup surface is in contact with the upper surface of the insulating layer and when the pickup surface is in contact with the upper surface of the insulating layer, wherein
the insulating layer is broken by the foreign material.

27.-33. (canceled)
